(19) United States
(12) Patent Application Publication
(10) Pub. No.: US 2002/0079957 A1
(43) Pub. Date: Jun. 27, 2002

(54) Reducing noise in a power signal

(76) Inventor: Thomas Gregory Hubert, Necedah, WI (US)

Correspondence Address: GARY A. WALPERT, Fish & Richardson P.C., 225 Franklin Street, Boston, MA, 02110-2804, US

(21) Appl. No.: 09/746,682

(22) Filed: Dec. 22, 2000

(51) Int. Cl. H03B 1/00

(52) U.S. Cl. 327/552

(57) ABSTRACT

An apparatus for reducing noise in an input periodic signal includes a delay circuit which produces a second periodic signal that corresponds to the input periodic signal, delays first frequency components of the second periodic signal that are below a predetermined threshold, and outputs, without substantial delay, second frequency components of the second periodic signal that are above the predetermined threshold. Another circuit removes the second frequency components from the input periodic signal.

### BACKGROUND

This invention relates generally to reducing noise in a periodic signal, such as a power signal, and to performing zero-cross detection using a component of the reduced-noise periodic signal.

A zero-cross detector used in utility grid applications detects when a main power signal, referred to as the “mains signal”, transitions between positive and negative voltages. Zero-cross detectors work by determining when the mains signal crosses a reference voltage. The information obtained from a zero-cross detector is used to determine the period, and thus the frequency, of the mains signal.

High-frequency and low-order harmonic noise is often coupled onto the mains signal. This noise can affect the accuracy of zero-cross detectors. For example, noise can produce multiple crossings of the threshold when there should only be a single crossing. Noise can also affect the timing of the threshold crossing, making the mains signal period seem longer or shorter than it is.

### SUMMARY

This invention reduces noise in a periodic signal during zero-cross detection. Both high-frequency noise and low-order harmonic noise are reduced, resulting in more accurate zero-cross detection.

In general, in one aspect, the invention is an apparatus, and corresponding method, for reducing noise in an input periodic signal. This aspect of the invention features a delay circuit which produces a second periodic signal that corresponds to the input periodic signal, delays first frequency components of the second periodic signal, and outputs, without substantial delay, second frequency components of the second periodic signal. A circuit removes the second frequency components from the input periodic signal. This aspect of the invention may also include one or more of the following features.

The first frequency components are below a predetermined threshold and the second frequency components are above the predetermined threshold. The second periodic signal is an inverse of the input periodic signal and the second frequency components are inverse to corresponding freguency components of the input periodic signal. The circuit is an adder which adds the second frequency components to the input periodic signal. The delay circuit is an all-pass, time-delay network.

In this aspect, the periodic signal may include a mains signal, harmonic noise signals at higher frequencies than the mains signal, and high-frequency noise at higher frequencies than the harmonic noise signals. The second frequency components that are removed from the input periodic signal include the high-frequency noise.

A zero-cross discriminator circuit removes the harmonic noise signals from the periodic signal. The zero-cross discriminator circuit includes an integrator which integrates the periodic signal over time and a comparator which compares integrated harmonic noise signals of the integrated input periodic signal to a reference voltage. The comparator ignores the integrated harmonic noise signals that do not exceed the reference voltage and outputs a signal when an integrated version of the mains signal crosses the reference voltage. A voltage source provides the reference voltage.

In general, in another aspect, the invention is directed to reducing noise in an input periodic signal. This aspect features producing a second periodic signal that corresponds to the input periodic signal, obtaining frequency components of the second periodic signal that are above a predetermined threshold, and removing frequency components from the input periodic signal that correspond to the frequency components of the second periodic signal. This aspect of the invention may include one or more of the following features.

The function of obtaining is performed by a time-delay network which passes the frequency components of the periodic signal that are above the predetermined threshold without substantial delay and which delays other frequency components of the periodic signal. The function of removing is performed by a circuit which combines the frequency components of the second periodic signal with the input periodic signal.

Other features and advantages of the invention will become apparent from the following description, including the claims and drawings.

### DESCRIPTION OF THE DRAWINGS

FIGS. 1 and 3 to 5 are block diagrams of circuitry for performing zero-cross detection on a power signal.

FIG. 2 shows graphs of the power signal and an inverted version of the power signal.

FIG. 6 is a flowchart showing a process performed by the circuitry of FIGS. 1 and 3 to 5.

FIG. 7 is a circuit diagram of one specific embodiment of the circuitry of FIGS. 1 and 3 to 5.

Like reference numerals in different figures indicate like elements.

### DESCRIPTION

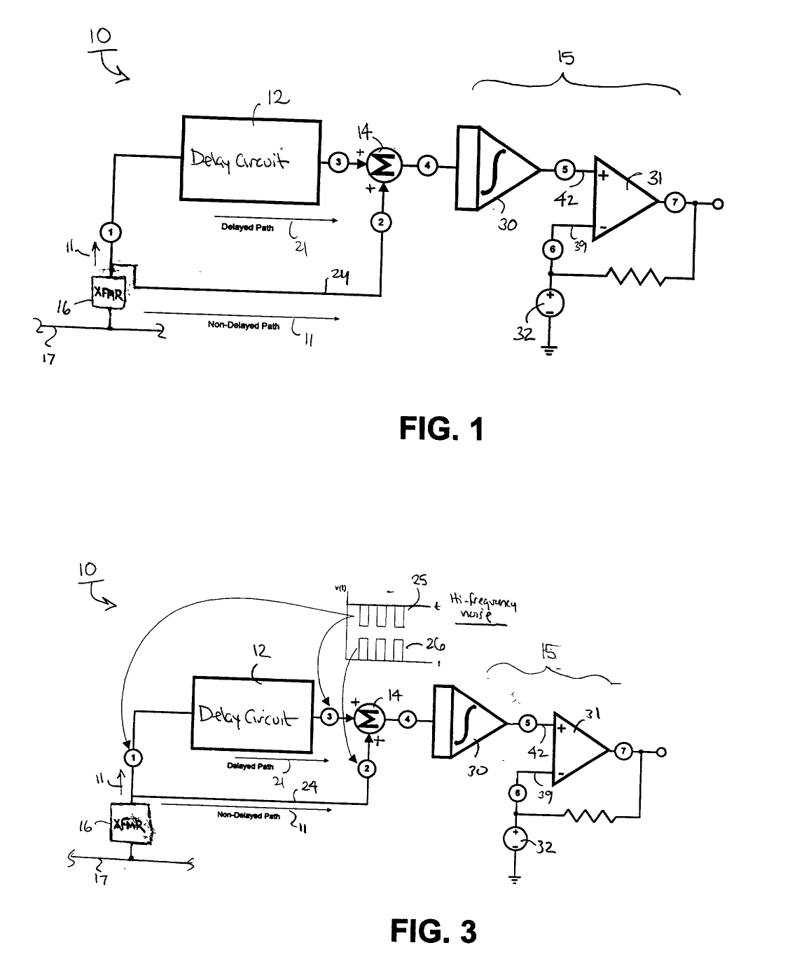

Referring to FIG. 1, circuitry 10 for performing zero-cross detection on an input power signal 11 is shown. Circuitry 10 may be used in electrical utility grid systems, such as uninterruptible power systems (UPS) and distributed magnetic energy storage (DSMES) systems. In these systems, the zero-cross detector serves as a first stage of a phase locked loop (PLL). PLLs in such systems are fast-reacting and, by themselves, exhibit poor noise immunity. Circuitry 10 supplies requisite noise immunity so that the PLLs can perform robustly in the typically noisy power grid environments.

Circuitry 10 includes a delay circuit 12, an adder 14, and zero-cross discriminator circuit 15. Power signal 11 is input to delay circuit 12 and adder 14 from a step-down transformer 16 connected to a high-voltage power line 17. Power signal 11 is a periodic (e.g., sinusoidal) signal that includes a mains signal, one or more low-order harmonic noise signals, and high-frequency noise. The harmonic noise signals are at higher frequencies than the mains signal and the high-frequency noise is at still higher frequencies than the harmonic noise signals. The mains signal is a voltage signal that is typically in the range of 45 Hz (Hertz) to 65 Hz, usually around 60 Hz. The harmonic noise signals are typically at 120 Hz, 180 Hz or 240 Hz (for a 60 Hz mains signal). The high-frequency noise is typically at higher frequencies of 300 Hz or greater.

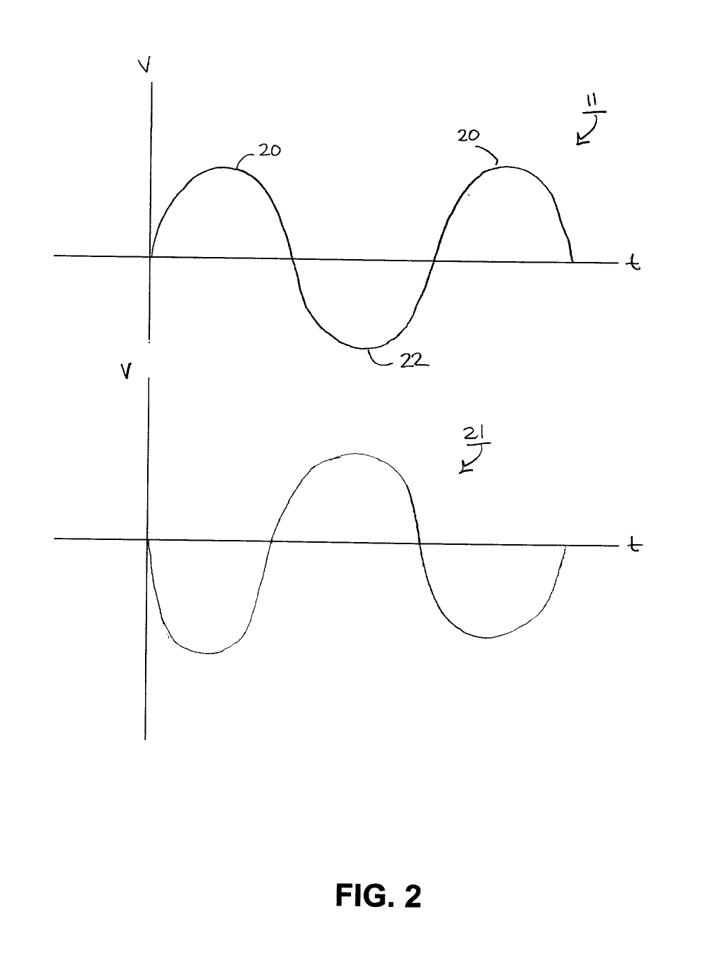

Delay circuit 12 is an all-pass, time-delay network that produces a duplicate, but inverted, version 21 of power signal 11. Referring to FIG. 2, what is meant by “inverted” here is that the positive portions 20 of power signal 11 are negative in duplicate signal 21 and the negative portions 22 of power signal 11 are positive in duplicate signal 21. Delay circuit 12 delays portions of the power signal that are between 45 Hz and 65 Hz, which correspond to the mains signal. The delay, in this embodiment, is approximately one millisecond.

Other frequencies of the power signal are passed through delay circuit 12 with monotonically decreasing amounts of delay. There may be some delay for lower-frequency signals, e.g., signals below 300 Hz. But, the higher-frequency signals that constitute the high-frequency noise, e.g., signals greater than 300 Hz, are passed through delay circuit 12 without substantial delay. As a result, these high-frequency noise signals arrive at adder 14 from delay circuit 12 at the same time as power signal 11 from non-delayed path 24.

The range of frequencies that are passed without substantial delay by delay circuit 12 may vary, depending upon its structure. The range of those frequencies may be changed, e.g., by varying capacitor and resistor values within delay circuit 12.

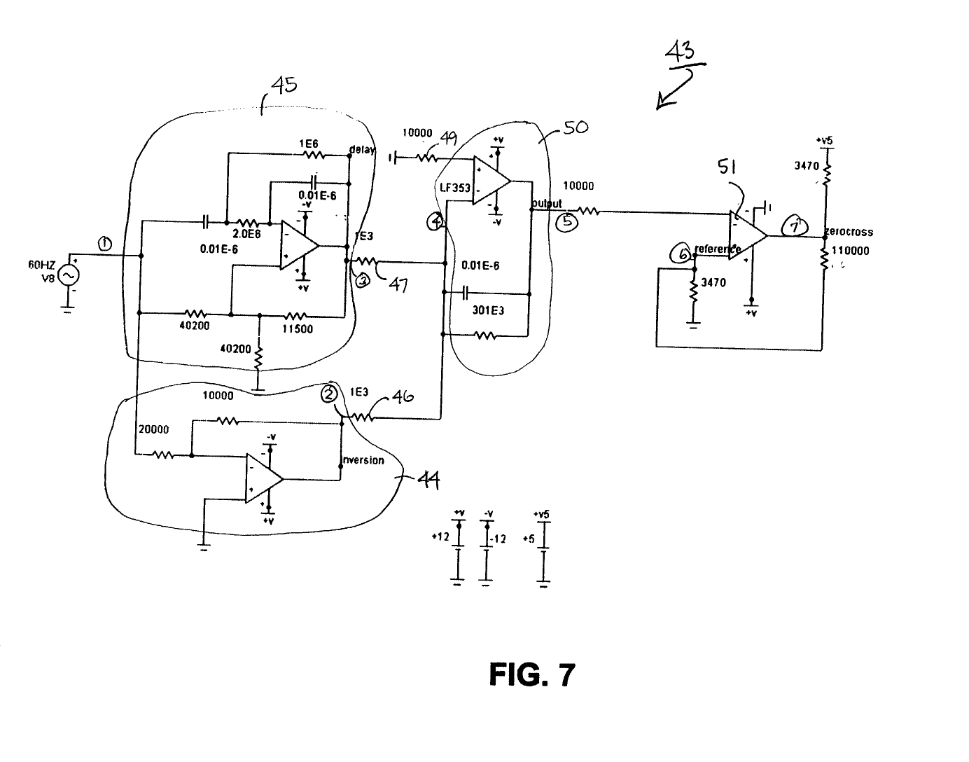

Input power signal 11 travels along non-delayed path 24 to adder 14. When power signal 11 arrives at adder 14, it is not inverted, although internal inversions may take place along non-delayed path 24, as described below with respect to FIG. 7.

Adder 14 is a summing junction that adds the inverted, non-delayed, high-frequency noise signals from delay circuit 12 to the input power signal 11 from non-delayed path 24. FIGS. 3, 4 and 5 show the circuitry FIG. 1 processing high-frequency noise, harmonic noise signals, and the mains signal, respectively. As shown in FIG. 3, the high-frequency noise signals 25 from delay circuit 12, because they are inverted, cancel the high-frequency noise signals 26 included in input power signal 11. This results in the removal of much of the high-frequency (e.g., >300 Hz) noise from the input power signal 11.

Some harmonic noise signals, in particular those at the upper end of the frequency spectrum (e.g., >300 Hz), will also be removed from the input power signal through the circuitry described above. However, lower-frequency harmonic noise signals (e.g., <300 Hz) will experience a slight delay in delay circuit 12. Thus, these inverted lower-order harmonic noise signals will not arrive at adder 14 at the same time as input power signal 11. As a result, the differential-addition operation will not necessarily remove the lower-order harmonic noise signals from power signal 11. Lower-order harmonic noise signals are completely removed when they occur as unipolar impulsive noise or stochastic noise, and are substantially attenuated in other cases (sustained periodic oscillation). The two processes, of removal, on one hand, and attenuation, on the other hand, as they pertain to these low-order harmonic noise components, are described below with reference to zero-cross discriminator circuit 15.

Zero-cross discriminator circuit 15 includes an integrator 30, a comparator 31, and a reference voltage source 32. Integrator 30 is a circuit that integrates, over time, the power signal output by adder 14, i.e., the summed power signals from adder 14. Integrator 30 includes circuit “memory”, which stores prior summed values of the power signal and adds a current value of the power signal to the prior summed values. One example of using integrator 30, delay circuit 12, and adder 14 to remove noise is as follows.

Consider a square, unipolar pulse of two-millisecond duration and amplitude greater than the comparator's threshold voltage 32. Time-delay circuit 12 provides an inverted duplicate of the input signal, but delayed slightly in time. When adder 14 sees the non-delayed signal, its output copies it until the time at which the adder sees the inverted, time-delayed duplicate. Up until this time, if the signal were passed directly to comparator 31, because it has greater amplitude than the threshold voltage 32, a false zero-cross indication would result.

However, integrator 30 is a circuit that integrates, over time, the power signal output by adder 14. Integrator 30 stores prior summed values of a signal's area and adds a current value of a signal's are to the prior summed values of a signals' area. The area of the pulse in the example will always be much less than the amplitude of the pulse signal because, area, in this case, is equivalent to the pulse's amplitude multiplied by the pulse's time duration. Since the value of time duration begins at zero (0), and increases at a constant rate to a value of time that never exceeds a value that is much, much less than one (1), the integrated pulse signal value is very small compared to the pulse amplitude (5 amplitude units ×0.002 time units =0.010 amplitude*time units; subsequently, 0.010<<5). Consequently, even without the benefit of the time delay, the integration provides significant attenuation of the noise pulse. Additionally, the mechanics of time-delay circuit 12 combined with adder 14 provide substantially more attenuation for signals with frequencies in the low-harmonic range, as follows.

When the inverted, time-delayed duplicate signal arrives at adder 14, the output of the adder transitions immediately to zero because the two instantaneous signal levels at the input to the adder are equal in amplitude and opposite in polarity. This effectively stops the integration process because the input to integrator 30 (which is the output of the adder 14) is now zero-valued. In this example, an additional attenuation factor of 0.5 has been applied to the pulse as a result of the mechanics of time-delay circuit 12 and adder 14 (5 amplitude units ×0.001 time units =0.005 amplitude*time units).

Additionally, the attenuation mechanics just described becomes exponentially more significant with increased frequency because the time-delay decreases exponentially with increasing frequency. This fact explains why in one embodiment, signals above approximately 300 Hertz become virtually common-mode signals to the differential adder 14. There is no time delay on signals at and above those frequencies; therefore, they are cancelled before they reach the integrator 30.

Finally, when the non-time-delayed pulse diminishes to zero amplitude, the time-delay mechanics cause a time-delayed, inverted pulse to appear at both at the input and the output of the adder 14. This represents negative area, which is added to the positive area previously summed. The total negative area accumulated by this negative signal will be equal to the total area accumulated up to the point before the time-delayed, inverted signal appeared at the input of the adder 14. Consequently, it will cancel the area previously accumulated, and there is no residual signal remaining at the output of the integrator 30 to be seen by comparator 31. This would not be the case for a simple integrator; for a low-pass filter, the effects of this pulse would linger in time duration, substantially.

This example illustrated the mechanics for a square, unipolar impulse. Mechanics for bipolar impulsive noise are identical, and mechanics for sustained periodic low-order harmonics are identical, as well, except sustained excitation by the noise signal means that the area contribution made by the noise is dynamic, leaving a ripple voltage superimposed on the desired mains signal; however, the mechanics described substantially attenuate such noise more than prior art filters and/or pure integrator-type detectors by an order of magnitude or more.

The mechanics illustrated above, by example, show that low-order harmonic noise signals of any type, impulsive or sustained, are substantially eliminated from the integrator's output before they can have a substantial adverse effect on zero-cross detection. By contrast, the mains signal, unlike the harmonic noise signals, is of an amplitude and a duration such that the summing of integrator 30 proceeds beyond a reference voltage.

Furthermore, in the embodiment described here, the gain of the integrator 30 is set so as to saturate the output of the comparator during most of the duration of positive and most of the duration of the negative half cycles of mains signal. The integrator's gain is likely set such that evaluation of the input signal and its noise components is allowed near the zero-crosses of the mains signal for a period of time roughly equal to twice the value of the time-delay of the time-delay network. Although this is not a requirement for the circuit to work well, this practice does reduce the possibility of integrator excursions that result from noise voltages that occur during most of the mains signal period by providing an additional margin of protection against very strong noise voltages that may occur from time to time.

Regardless of whether or not the integrator gain is set this way, circuits preceding the comparator 31 (in the direction of signal flow) provide most of the noise attenuation mechanics. The comparator's 31 primary task is to provide a square-wave output that exhibits the same frequency and period as the signal provided to its input. The mechanics of this task are described below.

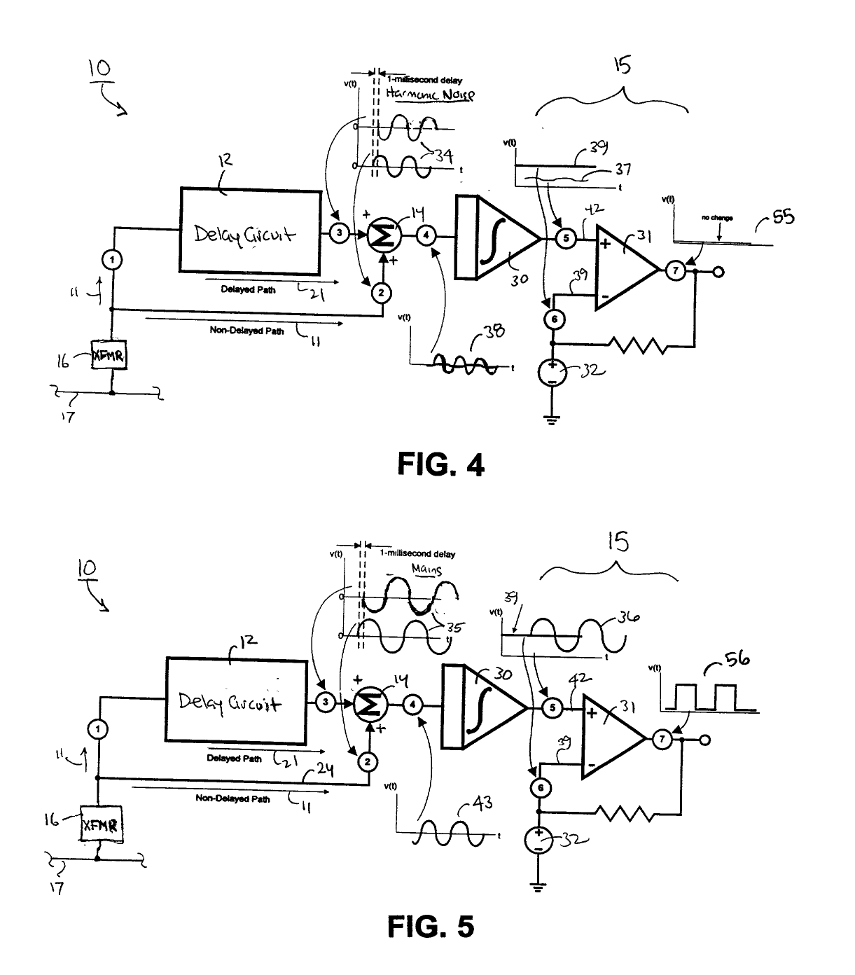

Referring now to FIGS. 4 and 5, an example of removing a sinusoidal harmonic noise component is shown. At the input of integrator 30, the power signal includes the summed mains signal 43 (FIG. 5) and the summed harmonic noise signals 38 (FIG. 4). Integrator 30 integrates signals 38 and 43. The resulting integrated harmonic noise signals 37 have lower amplitudes than the resulting integrated mains signal 36 due to the lower frequency and amplitude of the summed harmonic noise signals 38. This is because the area under the curve of the summed mains signal 43 is greater than the area under the curves of the summed harmonic noise signals 38, resulting in an integrated mains signal 36 (FIG. 5) that is higher in amplitude in both the negative and positive phases than the integrated harmonic noise signals 37 (FIG. 4).

Continuing with this example for the sake of illustration, comparator 31 compares the output signals from integrator 30 to a reference voltage, provided by reference voltage source 32. The output signals of integrator 30 include the integrated mains signal 36 (FIG. 5) and, in some instances, the integrated harmonic noise signals 37 (FIG. 4). The reference voltage 39 is set at the halfway point between the input voltage extremes seen at comparator 31, which correspond directly or proportionally to the output voltage extremes of integrator 30. In one embodiment, where the comparator output is +/− 15 volts, the reference voltage is set to zero volts. When the composite signal from integrator 30 transitions across the level of the reference voltage, the output of comparator 30 transitions, resulting in a square wave output, indicating that a zero-cross has been detected. The output of comparator 30 is typically fed back to a PLL or microcontroller (not shown) which implements a discrete-time time PLL in its firmware.

Comparator 31 exhibits a hysterisis feedback network. That is, comparator 31 prohibits noise still remaining on the output of integrator 30 from causing comparator 31 to switch its output multiple times.

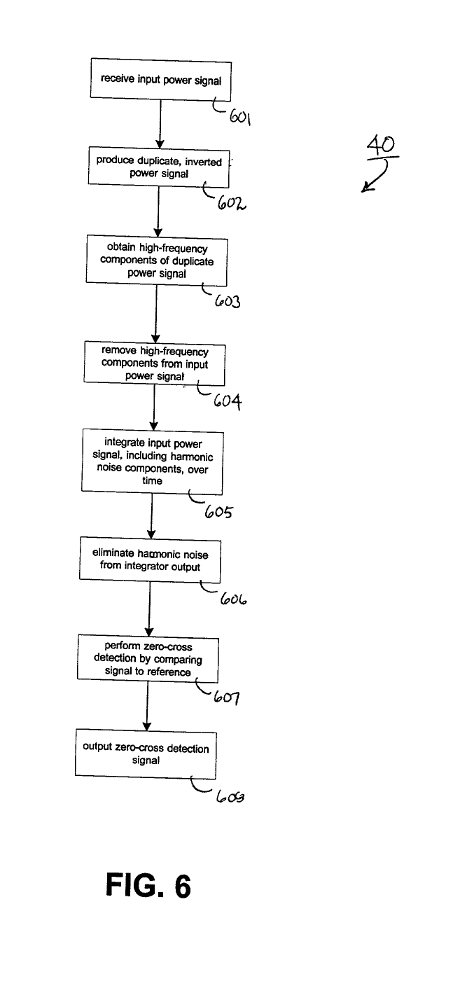

Referring to FIG. 6, a zero-cross detection process 40 is shown that is performed by circuitry 10. In process 40, circuitry 10 receives (601) an input power signal 11 from step-down transformer 16. Power signal 11 includes a mains signal, harmonic noise signals, and high-frequency noise, which are as described above.

Delay circuit 12 produces (602) a duplicate, but inverted, version of power signal 11. Delay circuit 12 obtains (603) the high-frequency components of the duplicate power signal 21 that are above a predetermined threshold, in this embodiment, 300 Hz. Delay circuit 12 does this by delaying the frequency components of duplicate signal 21 that are between 45 Hz and 65 Hz by approximately one millisecond and providing smaller amounts of delay to those signals that are between 65 Hz and 300 Hz. Signals above about 300 Hz are passed through delay circuit 12 with substantially no delay. Power signals typically do not contain signals that are less than 45 Hz, so signals less than 45 Hz are generally not passed.

Input power signal 11, which also propagates along non-delayed path 24, arrives at adder 14 at the same time as the high-frequency noise 25 of inverted duplicate signal 21. Adder 14 removes (604) the corresponding high-frequency noise from input power signal 11 by adding the high-frequency noise 25 of inverted duplicate signal 21 to input power signal 11. Since the high-frequency noise of duplicate signal 21 is inverted, i.e., opposite in polarity to the corresponding high-frequency noise 26 of input power signal 11, the two cancel. Accordingly, the input to integrator 30, i.e., the output of adder 14, is power signal 11 with its high-frequency noise removed.

Integrator 30 integrates (605) the power signal, including the attenuated harmonic noise components, that it receives from adder 14 over time. The integration includes integration of the mains signal and integration of the harmonic noise that was not eliminated by adder 14. In this regard, adder 14 does not totally eliminate harmonic noise below 300 Hz because that noise is delayed slightly by delay circuit 12, as shown in FIG. 4. As a result, when those components are added to power signal 11 at adder 14, there is not sufficient time coherence between the two signals such that harmonic noise is eliminated by differential circuit mechanics.

However, as noted above, an integrated harmonic noise signal 37 has a relatively small amplitude due to its greater frequency/shorter period and, potentially, its smaller amplitude. The integrated mains signal 36, by contrast, has a larger amplitude than the integrated harmonic noise signal due to its smaller frequency/longer period and, potentially, its greater amplitude. When comparator 31 compares the highly-attenuated and integrated harmonic noise signals 37 to the reference voltage 39, the resulting comparison does not produce an output signal 55, since the comparator only outputs a signal when its input voltage 42 exceeds the reference voltage 39. Thus, the harmonic noise signals are eliminated (606).

Thus, comparator 31 performs (607) zero-cross detection on the integrated mains signal 36 while ignoring the integrated harmonic noise signals 37. That is, the sinusoidal nature of the mains signal produces a sinusoidal integrated main signal 36, due to the addition of positive and negative portions of the sinusoid during the integration. The reference voltage 39 is selected so that it is substantially at the mid-point of integrated mains signal 36, making the crossings of the reference voltage 39 by the integrated mains signal 36 correspond to the zero-crossings of the mains signal.

Comparator 31 outputs (608) a signal 56 when the integrated mains signal 36 crosses the reference voltage 39. This signal corresponds to the zero-crossings of the mains signal, since the mains signal and its associated integrated signal have the same period, although they may be out of phase. Phase errors, however, can be corrected using a controller or the like (not shown). The zero-crossing signal is substantially uncorrupted by either low-order harmonic noise or high-frequency noise, since both have been removed/ignored, as described above.

The filtering performed by integrator 31 is not as effective at eliminating the high-frequency noise signals as the combination of delay circuit 12 and adder 14. For this reason, the high-frequency noise is reduced using delay circuit 12 and adder 14 rather than simply relying on integrator 31.

FIG. 7 is a circuit diagram of one specific embodiment 43 of the invention. It is noted, however, that the invention can be implemented in a number of different ways and is not limited to the circuitry of FIG. 7.

Comparing FIG. 1 and FIG. 7, the circled points one through seven on FIG. 7 correspond to the circled points one through seven on FIG. 1. Non-delayed path 24 (FIG. 1) is implemented in block 44 (FIG. 7). Block 44 includes a comparator, which performs a double inversion on the input power signal. The output of block 44 is thus a non-delayed power signal that is substantially identical to the input power signal. Delay circuit 12 (FIG. 1) is implemented in block 45 (FIG. 47). Delay circuit 12 duplicates, inverts, and delays the input power signal frequencies that are roughly between 45 Hz and 65 Hz (the mains signal). Frequencies above 300 Hz are output with substantially no delay and the other frequencies experience a delay, albeit one that is less than one millisecond. Resistors 46 and 47, in combination with resistor 49, comprise adder 14 (FIG. 1). Integrator 30 (FIG. 1) is implemented in block 50 (FIG. 7) and comparator 31 (FIG. 1) corresponds to comparator 51 (FIG. 7).

Circuitry 10, 43 (FIGS. 1, 7) for performing zero-cross detection can be used to perform zero-cross detection in a DSMES, such as those described in the following applications, which are hereby incorporated by reference into this application as if set forth herein in full: (1) U.S. patent application No. 09/240,751, entitled “Electric Utility Network With Superconducting Magnetic Energy Storage” and filed on Jan. 29, 1999; (2) U.S. Provisional Application No. 60/117,784, entitled “Electric Utility Network With Superconducting Magnetic Energy Storage” and filed on Jan. 29, 1999; (3) U.S. patent application Ser. No. 09/449,505, entitled “Method and Apparatus for Discharging a Superconducting Magnet” and filed on Nov. 24, 1999; (4) U.S. patent application Ser. No. 09/449,436, entitled “Method and Apparatus for Controlling a Phase Angle” and filed on Nov. 24, 1999; (5) U.S. patent application Ser. No. 09/449,378, entitled “Capacitor Switching” and filed on Nov. 24, 1999; (6) U.S. patent application Ser. No. 09/449,375, entitled “Method and Apparatus for Providing Power to a Utility Network” and filed on Nov. 24, 1999; (7) U.S. patent application Ser. No. 09/449,435, entitled “Electric Utility System with Superconducting Magnetic Energy Storage” and filed on Nov. 24, 1999; and (8) U.S. Provisional Application No. 60/167,377, entitled “Voltage Regulation of a Utility Power Network” and filed on Nov. 24, 1999.

The invention, however, is not limited to use with a DSMES system or power signals. It can be used with any periodic signal and any circuitry, power-related or otherwise, that uses zero-cross detection with reduced noise. The invention is also not limited to the specific frequencies or circuitry set forth herein. For example, the 300 Hz, 60 Hz, 120 Hz, etc. frequencies set forth above are representative and may change depending on system configurations and requirements. Likewise, referring to FIG. 1, the delayed path may be the non-inverted path and the non-delayed path may be the inverted path. The invention, in particular process 40, could also be performed, at least in part, using machine-executable code (e.g., computer software) running on a processor.

In this regard, process 40 may be implemented in hardware, software, or a combination of the two. For example, process 40 may be implemented using programmable logic such as a field programmable gate array (FPGA), and/or application-specific integrated circuits (ASICs).

Process 40 may be implemented in one or more computer programs executing on programmable computers that each include a processor, a storage medium readable by the processor (including volatile and non-volatile memory and/or storage elements), at least one input device, and one or more output devices. Program code may be applied to data entered using an input device to perform process 40 and to generate output information. The output information may be applied to one or more output devices.

Each such program may be implemented in a high level procedural or object-oriented programming language to communicate with a computer system. However, the programs can be implemented in assembly or machine language. The language may be a compiled or an interpreted language.

Each computer program may be stored on a storage medium or device (e.g., CD-ROM, hard disk, or magnetic diskette) that is readable by a general or special purpose programmable computer for configuring and operating the computer when the storage medium or device is read by the computer to perform process 40. Process 40 may also be implemented as a computer-readable storage medium, configured with a computer program, where, upon execution, instructions in the computer program cause the computer to operate in accordance with process 40.

Other embodiments not described herein are also within the scope of the following claims.

What is claimed is:

1. An apparatus for reducing noise in an input periodic signal, comprising:
a delay circuit which (i) produces a second periodic signal that corresponds to the input periodic signal, (ii) delays first frequency components of the second periodic signal, and (iii) outputs, without substantial delay, second frequency components of the second periodic signal; and
a circuit which removes the second frequency components from the input periodic signal.

2. The apparatus of claim 1, wherein the first frequency components are below a predetermined threshold and the second frequency components are above the predetermined threshold.

3. The apparatus of claim 1, wherein:
the second periodic signal is an inverse of the input periodic signal and the second frequency components are inverse to corresponding frequency components of the input periodic signal; and
the circuit comprises an adder which adds the second frequency components to the input periodic signal.

4. The apparatus of claim 1, wherein the delay circuit comprises an all-pass, time-delay network.

5. The apparatus of claim 1, wherein:
the periodic signal comprises a mains signal, harmonic noise signals at higher frequencies than the mains signal, and high-frequency noise at higher frequencies than the harmonic noise signals; and
the second frequency components that are removed from the input periodic signal comprise the high-frequency noise.

6. The apparatus of claim 5, further comprising a zero-cross discriminator circuit which removes the harmonic noise signals from the periodic signal.

7. The apparatus of claim 6, wherein the zero-cross discriminator circuit comprises:
an integrator which integrates the periodic signal over time; and
a comparator which compares integrated harmonic noise signals of the integrated input periodic signal to a reference voltage.

8. The apparatus of claim 7, wherein the comparator ignores the integrated harmonic noise signals that do not exceed the reference voltage and outputs a signal when an integrated version of the mains signal crosses the reference voltage.

9. The apparatus of claim 1, further comprising a voltage source to provide the reference voltage.

10. The apparatus of claim 1, wherein the periodic signal comprises a power signal.

11. A method of reducing noise in an input periodic signal, comprising:
producing a second periodic signal that corresponds to the input periodic signal;
delaying first frequency components of the second periodic signal;
outputting, without substantial delay, second frequency components of the second periodic signal; and
removing the second frequency components from the input periodic signal.

12. The method of claim 11, wherein the first frequency components are below a predetermined threshold and the second frequency components are above the predetermined threshold.

13. The method of claim 11, wherein:
the second periodic signal is an inverse of the input periodic signal and the second frequency components are inverse to corresponding frequency components of the input periodic signal; and
removing comprises adding the second frequency components to the input periodic signal.

14. The method of claim 11, wherein delaying is performed using an all-pass, time-delay network.

15. The method of claim 11, wherein:
the periodic signal comprises a mains signal, harmonic noise signals at higher frequencies than the mains signal, and high-frequency noise at higher frequencies than the harmonic noise signals; and
the second frequency components that are removed from the input periodic signal comprise the high-frequency noise.

16. The method of claim 15, further comprising removing the harmonic noise signals from the periodic signal.

17. The method of claim 16, wherein removing the harmonic noise signals comprises:
integrating the periodic signal over time; and
comparing integrated harmonic noise signals of the integrated input periodic signal to a reference voltage.

18. The method of claim 17, wherein comparing comprises:
ignoring the integrated harmonic noise signals that do not exceed the reference voltage; and
outputting a signal when an integrated version of the mains signal crosses the reference voltage.

19. The method of claim 11, wherein the periodic signal comprises a power signal.

20. An apparatus for reducing noise in an input periodic signal, comprising:
means for producing a second periodic signal that corresponds to the input periodic signal;
means for obtaining frequency components of the second periodic signal that are above a predetermined threshold; and
means for removing frequency components from the input periodic signal that correspond to the frequency components of the second periodic signal.

21. The apparatus of claim 20, wherein the obtaining means comprises a time-delay network which passes the frequency components of the periodic signal that are above the predetermined threshold without substantial delay and which delays other frequency components of the periodic signal.

22. The apparatus of claim 20, wherein the removing means comprises a circuit which combines the frequency components of the second periodic signal with the input periodic signal.

23. A method of reducing noise in an input periodic signal, comprising:
producing a second periodic signal that corresponds to the input periodic signal;
obtaining frequency components of the second periodic signal that are above a predetermined threshold; and
removing frequency components from the input periodic signal that correspond to the frequency components of the second periodic signal.

24. A computer-readable medium that stores computer-executable instructions for reducing noise in an input periodic signal, the instructions causing a computer to:
produce a second periodic signal that corresponds to the input periodic signal;
delay first frequency components of the second periodic signal;
output, without substantial delay, second frequency components of the second periodic signal; and
remove the second frequency components from the input periodic signal.

25. A computer-readable medium that stores computer-executable instructions for reducing noise in an input periodic signal, the instructions causing a computer to:
produce a second periodic signal that corresponds to the input periodic signal;
obtain frequency components of the second periodic signal that are above a predetermined threshold; and
remove frequency components from the input periodic signal that correspond to the frequency components of the second periodic signal.

26. An apparatus for reducing noise in an input periodic signal, comprising:
means for producing a second periodic signal that corresponds to the input periodic signal;
means for delaying first frequency components of the second periodic signal;
means for outputting, without substantial delay, second frequency components of the second periodic signal; and
means for removing the second frequency components from the input periodic signal.
